(19) United States
(12) Patent Application Publication
(10) Pub. No.: US 2025/0289975 A1
(43) Pub. Date: Sep. 18, 2025

(54) CURED PRODUCT AND PRINTED WIRING BOARD

(71) Applicant: TAIYO HOLDINGS CO., LTD., Hiki-gun, Saitama-ken (JP)

(72) Inventors: Tsutomu TAKAHASHI, Hiki-gun, Saitama-ken (JP); Fumitaka KATO, Hiki-gun, Saitama-ken (JP); Kayoko TOKUMITSU, Hiki-gun, Saitama-ken (JP); Natsuki ITO, Hiki-gun, Saitama-ken (JP); Daichi OKAMOTO, Hiki-gun, Saitama-ken (JP); Masayuki SHIMURA, Hiki-gun, Saitama-ken (JP)

(73) Assignee: TAIYO HOLDINGS CO., LTD., Hiki-gun, Saitama-ken (JP)

(21) Appl. No.: 18/851,834

(22) PCT Filed: Mar. 27, 2023
(86) PCT No.: PCT/JP2023/012305

§ 371 Date: May 16, 2025

(30) Foreign Application Priority Data
Mar. 28, 2022 (JP) 2022-052565

(51) Int. Cl. C09D 151/08; C09D 4/06; C09D 7/62; H05K 3/12

(52) U.S. Cl. CPC C09D 151/08; C09D 4/06; C09D 7/62; H05K 3/1258

(57) ABSTRACT

Provided is a cured product of a photosensitive resin composition which contains inorganic fillers while maintaining an excellent resolution, and can also reduce warpage of a board when the electronic components are mounted. A cured product of a photosensitive resin composition comprising at least an alkali-soluble resin, a photoinitiator, and an inorganic filler, wherein the inorganic filler is contained in 85% or less by mass based on the total amount of the photosensitive resin composition, the elastic modulus of the cured product is 4 to 12 GPa, and the cured product satisfies the following condition: A≤0.3%, and B−A≤0.3, where A (%) is the water absorption rate of the cured product after leaving it for 60 minutes in an environment with a temperature of 25° C. and a relative humidity of 10%, and where B (%) is the water absorption rate of the cured product after leaving it for 60 minutes in an environment with a temperature of 25° C. and a relative humidity of 60%.

### BACKGROUND OF THE INVENTION

### Field of the Invention

The present invention relates to a cured product, and more specifically, to a cured product of photosensitive resin composition which can be used preferably as an insulating layer such as a solder resist layer, and to a printed circuit board using the cured product.

### Background Art

In printed wiring boards used for electronic apparatuses, when electronic components are mounted on the printed wiring board, a solder resist layer is in general formed in an area other than connection holes on the board on which a circuit pattern is formed for the purpose of preventing soldering from adhering to unnecessary areas of the printed wiring board in the steps such as reflow soldering. It is currently mainstream that a solder resist layer is formed by a so-called photosensitive solder resist, wherein a photosensitive resin composition is applied onto a base material and dried; pattern formation is carried out by exposure and development; and then a resin after the pattern formation is subjected to final curing by heating or light irradiation. In addition, what has been also proposed is the use of a photosensitive dry film, wherein the solder resist layer is formed without using the above liquid photosensitive resin composition.

These photosensitive resin composition and photosensitive dry film contain an alkali-soluble photosensitive resin component which enable to be exposed and developed. They also contain other photopolymerizable monomers as necessary, and thermosetting components such as epoxy resins with consideration for thermal resistance and the substrate adhesion. Further, to reduce the coefficient of linear expansion to prevent detachment of the solder resist layer and warpage of the board, an inorganic filler is sometimes combined to a photosensitive resin composition (Patent Document 1 or the like).

On the other hand, as the amount of inorganic filler combined increases, a cured product with a low linear expansion coefficient is obtained. However, the resolution at the time of exposure tends to decrease. Therefore, as a photosensitive resin composition which contains inorganic fillers while maintaining a high resolution, a certain photoinitiator has been used alone or used in combination with a sensitizer (Patent Document 2 or the like).

### PRIOR ART DOCUMENTS

### Patent Documents

Patent Document 1: JP 2001-72834 A1
Patent Document 2: WO 2015-16362 A1

### SUMMARY OF THE INVENTION

The printed wiring board manufactured in the manner described above is placed in a low-humidity environment such as in a pouch packaging, and removed from the pouch to use at the step of mounting the electronic component thereon. If a certain amount of time passes between unpacking the board from the pouch packaging and mounting the electronic components on the board, the board may warp to result a mounting defect. Meanwhile, although a cured product made by using the photosensitive resin composition with a high inorganic filler content as described above is less likely to warp the board when an electronic component is mounted thereon, it tends to have a lower resolution.

That is, an object of the present invention is to provide a cured product of photosensitive resin composition which has high resolution, and can also reduce warpage of a board when the electronic components are mounted.

The present inventors investigated the above problem to find that a photosensitive resin composition, in which the amount of inorganic filler in a photosensitive resin composition is below a certain amount, and also the water absorption rate of a cured product cured under the predetermined curing conditions is less than a certain value, enables to reduce warping while maintaining an excellent resolution even when used as a printed circuit board. The present invention is based on such findings. That is, the gist of the present invention is as follows.
[1] A cured product of photosensitive resin composition comprising at least an alkali-soluble resin, a photoinitiator, and an inorganic filler, wherein
   the inorganic filler is contained in 85% or less by mass based on the total amount of the photosensitive resin composition,
   the elastic modulus of the cured product is 4 to 12 GPa, and
   the cured product satisfies the following condition:

$$A \leq 0.3 \%$$

$$and$$

$$B - A \leq 0.3$$

where A (%) is the water absorption rate of the cured product after leaving it for 60 minutes in an environment with a temperature of 25° C. and a relative humidity of 10%, and
   where B (%) is the water absorption rate of the cured product after leaving it for 60 minutes in an environment with a temperature of 25° C. and a relative humidity of 60%.
[2] The cured product according to [1], wherein the inorganic filler is contained in the amount of 45 to 65% by mass based on the total amount of the photosensitive resin composition.
[3] The cured product according to [1], wherein the inorganic filler is surface-treated with a silane coupling agent.
[4] The cured product according to [1], wherein the photosensitive resin composition further comprises a sensitizer in the amount of 0.01 to 10% by mass based on the total amount of the photosensitive resin composition.
[5] The cured product according to [4], wherein the sensitizer is anthraquinone-based sensitizer having an ester bond.
[6] A printed wiring board having a board and a coating film composed of the cured product according to any one of [1] to [5] provided on the board.

According to the present invention, a cured product containing an inorganic filler in a predetermined ratio or less and having a predetermined water absorption rate characteristic enables to achieve a cured product of photosensitive resin composition which contains an inorganic filler while maintaining a high resolution, and can also reduce warpage of a board when the electronic components are mounted.

### DETAILED DESCRIPTION OF THE INVENTION

### [Cured Product]

The present invention is to provide a cured product of photosensitive resin composition comprising at least an alkali-soluble resin, a photoinitiator, and an inorganic filler, wherein the elastic modulus of the cured product is 4 to 12 GPa, and the cured product satisfies the following condition: A≤0.3% and B−A≤0.3, where A (%) is the water absorption rate of the cured product after leaving it for 60 minutes in an environment with a temperature of 25° C. and a relative humidity of 10%, and where B (%) is the water absorption rate of the cured product after leaving it for 60 minutes in an environment with a temperature of 25° C. and a relative humidity of 60%. To adjust the composition of photosensitive resin composition and the curing conditions so that the amount of the inorganic filler is contained in the amount of 85% or less by mass based on the total amount of the photosensitive resin composition and the water absorption rate of the cured product is within the predetermined range as described above, enables to achieve a high resolution while reducing warpage of a board when the electronic components are mounted. The reason for this is uncertain but it is considered as follows.

While the water absorption rate of a cured product when a photosensitive resin composition is cured depends on the components constituting the photosensitive resin composition, it is considered that, not only the water absorption rate in the type of the component, but also the interaction between the components constituting the cured product such as the degree of cross-linking is involved. In the present invention, the cured product has an elastic modulus in the range of 4 to 12 GPa. The lower water absorption rate of the cured product reduces more degree of warpage of the printed wiring board. In addition, by using a photosensitive resin composition with the low water absorption rate when prepared as such cured product, the warpage of the substrate, which occurs when the photosensitive resin composition is applied onto the board or when a dried coating film of photosensitive resin composition (a dry film) is laminated on the board, is also reduced. As a result, it is considered that the resolution degradation due to the warpage of the board is reduced. In other words, it is considered that the warpage of board in both before and after a photosensitive resin composition is cured can be reduced at the same time, by adjusting the composition of photosensitive resin composition and the curing conditions so that the elastic modulus is within a predetermined range and the water absorption rate is below a certain value in the cured product.

The elastic modulus of the cured product according to the present invention is preferably in the range of 6 to 12 GPa, and more preferably in the range of 7 to 9 GPa from the viewpoint of the resolution and the warpage reduction of the board. It is to be noted that, in the present invention, the elastic modulus of a cured product refers to a value calculated from the stress-strain curve measured in accordance with JIS K 7127. Specifically, the tensile test is performed on a cured product by using a tensile testing machine under the condition of a tensile speed of 1 mm/min at 25° C., and the elastic modulus is determined from the slope of line calculated between stress values of 2N and 7N from the resulting stress-strain curve.

The value of A of the cured product according to the present invention is preferably 0.25% or less, and more preferably 0.2% or less from the viewpoint of the resolution and the warpage reduction of a board. In other words, the cured product preferably has the low water absorption rate in dry condition (relative humidity of 10%). In addition, the value of B−A is preferably 0.25% or less, and more preferably 0.2%. Yet, in the present invention, the water absorption rate of the cured product can be measured as follows.

First, a photosensitive resin composition is applied over the entire surface of copper clad laminate board (MCL-E-770G manufactured by Showa Denko K.K., copper thickness 18 μm) which has the thickness of 200 μm and the size of 100×100 mm as a support so that the cured film thickness is 20 μm, resulting a dried coating film. Thereafter, the dried coating film is subjected to exposure, then heated to cure the coating, and subsequently the cured coating is detached from the support to obtain the cured product. The detached cured product is placed on a weighing dish, and the mass of cured product after leaving it for 1 hour in an environment at 100° C. (absolute dry condition) is set as W₀. It is to be noted that the amount of the sample placed on the weighing dish may be about 10 to 50 mg.

Then, the mass of the cured product after leaving it for 60 minutes in an environment with a temperature of 25° C. and a relative humidity of 10% is measured (the resulting mass at this time is set as W₁₀).

Also, the mass of the cured product after leaving it for 60 minutes in an environment with a temperature of 25° C. and a relative humidity of 60% is measured (the resulting mass at this time is set as W₆₀).

The water absorption rates A and B of the cured product are defined as follows.

$$The water absorption rate A ( \% ) = ( {W}_{10} - {W}_{0} ) / {W}_{0} \times 100$$

$$The water absorption rate B ( \% ) = ( {W}_{60} - {W}_{0} ) / {W}_{0} \times 100$$

The measurement procedure described as an example above is for the water absorption rate of a cured product formed from a photosensitive resin composition. The same procedure can also be performed without saying when a coating of cured product is provided in advance on a support such as a copper clad laminate board. For example, if a coating of cured product is provided on the support in advance, a sample piece detached from or scraped off the surface of cured product can be used to measure the each value of W₀, W₁₀, and W₆₀ as described above, resulting the value of the water absorption rate A and water absorption rate B.

The elastic modulus and water absorption rate of a cured product can be controlled by adjusting components of photosensitive resin composition, the combining ratio of each of the components, the curing conditions, and the like as appropriate. Hereinafter, each component constituting the photosensitive resin composition according to the present invention will be described.

### <Alkali-Soluble Resin>

Alkali-soluble resins can be any resin which is soluble in alkali, and a commonly-used known alkali-soluble resin is used. One kind of alkali-soluble resin can be used solely; or two or more kinds can be used in combination. Examples of alkali-soluble resins include water-soluble resins such as carboxyl group-containing resins and phenolic hydroxyl group-containing resins. Among these, due to their excellent development properties, carboxyl group-containing resins and phenolic hydroxyl group-containing resins are preferable, and carboxyl-containing resins are even more preferable. As the alkali-soluble resin contains a carboxyl group-containing resin, which allows it to have alkaline development properties. In addition, from the viewpoint of photosensitive, it is preferred to have, in addition to the carboxyl group, an ethylenically unsaturated bond in the molecule; but a carboxyl group-containing photosensitive resin that does not have the ethylenically unsaturated double bond may be used solely. In cases where the carboxyl group-containing resin does not have the ethylenically unsaturated double bond, it is required to be used in conjunction with a photopolymerizable monomer for the purpose of making the composition photocurable. The ethylenically unsaturated double bond is preferably derived from acrylic acid or methacrylic acid or a derivative thereof.

Specific examples of carboxyl group-containing resins include compounds as described below (may be either oligomers or polymers). It is to be noted that the term (meth)acrylate, when used in the present description, is a generic term of an acrylate, a methacrylate, and a mixture thereof; and the same is applied to other similar expressions.
(1) A carboxyl group-containing resin obtained by copolymerization of an unsaturated carboxylic acid such as (meth)acrylic acid with an unsaturated group-containing compound such as styrene, α-methylstyrene, lower alkyl (meth)acrylate, or isobuthylene.
(2) A carboxyl group-containing urethane resin obtained by a polyaddition reaction of a diisocyanate such as aliphatic diisocyanate, branched aliphatic diisocyanate, alicyclic diisocyanate, or aromatic diisocyanate, with a carboxyl group-containing dialcohol compound such as dimethylolpropionic acid or dimethylolbutanoic acid, and a diol compound such as polycarbonate polyol, polyether polyol, polyester polyol, polyolefin polyol, acrylic polyol, bisphenol A alkylene oxide adduct diol, or a compound having a phenolic hydroxyl group and an alcoholic hydroxyl group.
(3) A carboxyl group-containing photosensitive urethane resin obtained by a polyaddition reaction of diisocyanate with a partially modified acid anhydride of a reaction product of a bifunctional epoxy resin such as bisphenol A type epoxy resin, hydrogenated bisphenol A type epoxy resin, bisphenol F type epoxy resin, bisphenol S type epoxy resin, bixylenol type epoxy resin, or biphenol type epoxy resin and monocarboxylic acid compound having a ethylenically unsaturated double bond such as (meta) acrylic acid, a carboxyl group-containing dialcohol compound, and a diol compound.
(4) A carboxyl group-containing photosensitive urethane resin obtained by adding a compound having one hydroxyl group and one or more (meth)acryloyl groups in the molecule such as hydroxyalkyl (meth)acrylate during synthesis of the resin in (2) or (3) above to be terminally (meth)acrylated.
(5) A carboxyl group-containing photosensitive urethane resin obtained by adding a compound having one isocyanate group and one or more (meth)acryloyl groups in the molecule such as equimolar reaction product of isophorone diisocyanate and pentaerythritol triacrylate during synthesis of the resin in (2) or (3) above to be terminally (meth)acrylated.
(6) A carboxyl group-containing photosensitive resin obtained by bringing a bifunctional (solid) epoxy resin or a (solid) epoxy resin with two or more functionalities into reaction with (meth)acrylic acid and adding a dibasic acid anhydride to the hydroxyl group present in a side chain.
(7) A carboxyl group-containing photosensitive resin obtained by bringing a multifunctional epoxy resin into reaction with (meth)acrylic acid and adding a dibasic acid anhydride to the generated hydroxyl group, which multifunctional epoxy resin is obtained by epoxidation of a hydroxyl group of bifunctional (solid) epoxy resin with epichlorohydrin.
(8) A carboxyl group-containing polyester resin obtained by bringing a bifunctional oxetane resin into reaction with dicarboxylic acid such as adipic acid, phthalic acid, or hexahydrophthalic acid and adding a dibasic acid anhydride such as phthalic anhydride, tetrahydrophthalic anhydride, or hexahydrophthalic anhydride to the generated primary hydroxyl group.
(9) A carboxyl group-containing photosensitive resin obtained by bringing an epoxy compound having plural epoxy groups in one molecule into reaction with a compound having at least one alcoholic hydroxyl group and one phenolic hydroxyl group in one molecule, such as p-hydroxyphenethyl alcohol, and an unsaturated group-containing monocarboxylic acid such as (meth)acrylic acid, and bringing the alcoholic hydroxyl group of the obtained reaction product into reaction with a polybasic anhydride such as maleic anhydride, tetrahydrophthalic anhydride, trimellitic anhydride, pyromellitic anhydride, or adipic acid.
(10) A carboxyl group-containing photosensitive resin obtained by bringing a compound having plural phenolic hydroxyl groups in one molecule into reaction with alkylene oxide such as ethylene oxide or propylene oxide; bringing the obtained reaction product into reaction with an unsaturated group-containing monocarboxylic acid; and bringing the obtained reaction product into reaction with a polybasic anhydride.
(11) A carboxyl group-containing photosensitive resin obtained by bringing a compound having plural phenolic hydroxyl groups in one molecule into reaction with a cyclic carbonate compound such as ethylene carbonate or propylene carbonate; bringing the obtained reaction product into reaction with an unsaturated group-containing monocarboxylic acid; and bringing the obtained reaction product into reaction with a polybasic anhydride.
(12) A carboxyl group-containing photosensitive resin obtained by further adding a compound having one epoxy group and one or more (meth)acryloyl groups in one molecule to the resin in any of (1) to (11) above.

One kind of these carboxyl group-containing resins can be used, not limited to those listed above, and may be used alone, or two or more kinds may be mixed and used.

The acid value of the carboxyl group-containing resin is preferably 40 to 150 mg KOH/g. By making the acid value of the carboxyl group-containing resin 40 mg KOH/g or more, good alkaline development is possible. In addition, by making the acid value 150 mg KOH/g or less, It is easy to draw excellent resist patterns. More preferably, the acid value is 50 to 130 mg KOH/g.

A weight average molecular weight of the carboxyl group-containing resin varies in resin backbone and in general preferably 2,000 to 150,000. By making the weight average molecular weight 2,000 or more, tack-free performance and resolution can be improved. In addition, by making a weight average molecular weight 150,000 or less, development properties and preservation stability can be improved. More preferably, a weight average molecular weight is 5,000 to 15,000. Yet, the weight average molecular weight can be measured by the gel permeation chromatography (GPC),

The amount of the carboxyl group-containing resin is preferably 10 to 50% by mass in the photosensitive resin composition in terms of solid content. By making the amount 10% by mass or more, the coating film strength can be improved. In addition, by making the amount 50% by mass or less, an appropriate viscosity is attained and the printing property is improved. More preferably, the amount is 10 to 30% by mass.

### <Photoinitiator>

The photosensitive resin composition according to the present invention includes a photoinitiator to photopolymerize. The conventionally known photoinitiator can be used, and for example, can include: a-aminoacetophenone-based photoinitiator such as 2-methyl-1-[4-(methylthio)phenyl]-2-morpholino-1-propanone, 2-benzyl-2-dimethylamino-1-(4-morpholinophenyl)-butane-1-one, 2-(dimethylamino)-2-[(4-methylphenyl)methyl]-1-[4-(4-morpholinyl)phenyl]-1-butanone, and N,N-dimethylaminoacetophenone: hydroxyacetophenone-based photoinitiator such as 1-hydroxy-cyclohexylphenylketone, 1-[4-(2-hydroxyethoxy)-phenyl]-2-hydroxl-2-methyl-1-propane-1-one, 2-hydroxy-1-{4-[4-(2-hydroxy-2-methyl-propionyl)-benzyl] phenyl}-2-methyl-propane-1-one, and 2-hydroxy-2-methyl-1-phenylpropane-1-one; acylphosphine oxide-based photoinitiator such as bis-(2,6-dichlorobenzoyl)phenylphosphine oxide, bis-(2,6-dichlorobenzoyl)-2,5-dimethylphenylphosphine oxide, bis-(2,6-dichlorobenzoyl)-4-propylphenylphosphine oxide, bis-(2,6-dichlorobenzoyl)-1-naphthylphosphine oxide, bis-(2,6-dimethoxybenzoyl)phenylphosphine oxide, bis-(2,6-dimethoxybenzoyl)-2,4,4-trimethylpentylphosphine oxide, bis-(2,6-dimethoxybenzoyl)-2,5-dimethylphenylphosphine oxide, bis-(2,4,6-trimethylbenzoyl)-phenylphosphine oxide, 2,6-dimethoxybenzoyl diphenylphosphine oxide, 2,6-dichlorobenzoyl diphenylphosphine oxide, 2,4,6-trimethylbenzoyl phenylphosphinic acid methyl ester, 2-methylbenzoyl diphenylphosphine oxide, pivaloyl phenylphosphinic acid isopropyl ester, and 2,4,6-trimethylbenzoyl diphenylphosphine oxide; benzoin-based photoinitiator such as benzoin, benzyl, benzoin methyl ether, benzoin ethyl ether, benzoin n-propyl ether, benzoin isopropyl ether, and benzoin n-butyl ether; benzoin alkyl ether-based photoinitiator; benzophenone-based photoinitiator such as benzophenone, p-methylbenzophenone, Michler's ketone, methylbenzophenone, 4,4′-dichlorobenzophenone, and 4,4′-bisdiethylaminobenzophenone; acetophenone-based photoinitiator such as acetophenone, 2,2-dimethoxy-2-phenylacetophenone, 2,2-diethoxy-2-phenylacetophenone, 1,1-dichloroacetophenone, 1-hydroxycyclohexyl phenylketone, and 2-methyl-1-[4-(methylthio)phenyl]-2-morpholino-1-propanon; thioxanthone-based photoinitiator such as thioxanthone, 2-ethyl thioxanthone, 2-isopropyl thioxanthone, 2,4-dimethyl thioxanthone, 2,4-diethyl thioxanthone, 2-chlorothioxanthone, and 2,4-diisopropyl thioxanthone; anthraquinone-based photoinitiator such as anthraquinone, chloroanthraquinone, 2-methylanthraquinone, 2-ethylanthraquinone, 2-tert-butylanthraquinone, 1-chloroanthraquinone, 2-amylanthraquinone, and 2-aminoanthraquinone; ketal-based photoinitiator such as acetophenone dimethyl ketal and benzyl dimethyl ketal; benzoic acid ester-based photoinitiator such as ethyl-4-dimethylaminobenzoate, 2-(dimethylamino)ethyl benzoate, and p-dimethylbenzoic acid ethyl ester; oxime ester-based photoinitiator such as 1,2-octanedione, 1-[4-(phenylthio)phenyl]-, 2-(O-benzoyloxime)], ethanone, 1-[9-ethyl-6-(2-methylbenzoyl)-9H-carbazole-3-yl]-, and 1-(O-acetyloxime); and titanocene-based photoinitiator such as bis(η5-2,4-cyclopentadiene-1-yl)-bis(2,6-difluoro-3-(1H-pyrrole-1-yl)phenyl)titanium and bis(cyclopentadienyl)-bis[2,6-difluoro-3-(2-(1-pyl-1-yl)ethyl)phenyl]titanium. One kind of photoinitiators may be used solely; or two or more kinds may be used in combination.

Examples of commercially available a-aminoacetophenone-based photoinitiators include Omnirad 907, 369, 369E, and 379 manufactured by IGM Resins B.V.

Examples of commercially available acylphosphine oxide-based photoinitiators include Omnirad 819 manufactured by IGM Resins B.V.

Examples of commercially available titanocene-based photoinitiators include JMT-784 manufactured by Yueyang Kimoutain Sci-tech Co., Ltd., and GR-FMT manufactured by Hubei Gurun Technology Co., Ltd, etc.

In addition, a photoinitiator having two oxime ester groups in the molecule can be suitably used; and specifics examples thereof include an oxime ester compound having a carbazole structure represented by the following general formula (I).

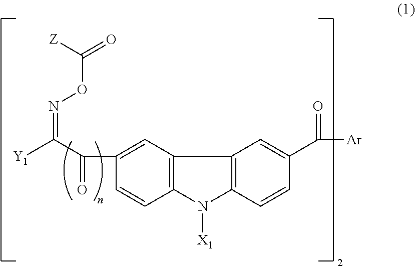

In the above formula, X represents a hydrogen atom, an alkyl group having 1 to 17 carbon atoms, an alkoxy group having 1 to 8 carbon atoms, a phenyl group, a phenyl group (substituted with an alkylamino group or dialkylamino group having an alkyl group having 1 to 17 carbon atoms, an alkoxy group having 1 to 8 carbon atoms, an amino group, or an alkyl group having 1 to 8 carbon atoms), or a naphthyl group (substituted with an alkylamino group or dialkylamino group having an alkyl group having 1 to 17 carbon atoms, an alkoxy group having 1 to 8 carbon atoms, an amino group, or an alkyl group having 1 to 8 carbon atoms); Y and Z represent each a hydrogen atoms, an alkyl group having 1 to 17 carbon atoms, an alkoxy group having 1 to 8 carbon atoms, a halogen group, a phenyl group, a phenyl group (substituted with an alkylamino group or dialkylamino group having an alkyl group having 1 to 17 carbon atoms, an alkoxy group having 1 to 8 carbon atoms, an amino group, or an alkyl group having 1 to 8 carbon atoms), a naphthyl group (substituted with an alkylamino group or dialkylamino group having an alkyl group having 1 to 17 carbon atoms, an alkoxy group having 1 to 8 carbon atoms, an amino group, or an alkyl group having 1 to 8 carbon atoms), an anthryl group, a pyridyl group, a benzofuryl group, or a benzothienyl group; Ar represents an alkylene having 1 to 10 carbon atoms, vinylene, phenylene, biphenylene, pyridylene, naphthylene, thiophene, anthrylene, thienylene, furylene, 2,5-pyrrole-diyl, 4,4′-stilbene-diyl, or 4,2′-styrene-diyl; and n is an integer of 0 or 1.)

In particular, preferred is that an oxime ester photoinitiator represented by the above formula wherein X₁ and Y₁ are each a methyl group or an ethyl group; Z is methyl or phenyl; n is 0; and Ar is phenylene, naphthylene, thiophene, or thienylene.

The amount of the photoinitiator in the photosensitive resin composition is preferably 1 to 50 parts by mass, and more preferably 1 to 20 parts by mass based on 100 parts by mass of the carboxyl group-containing resin in terms of solid content. As a result, the curability in deep portions can be improved.

### <Sensitizer>

The photosensitive resin composition of the present invention preferably contains in combination with the above-mentioned photoinitiator and a sensitizer. The combination use with a sensitizer can reduce the water absorption rate of the cured product without increasing the amount of inorganic filler described below, and provide a hard cured product with good resolution.

The conventionally known sensitizer can be used, and examples can include, for instance, a benzoin compound, an anthraquinone compound, a thioxanthone compound, a ketal compound, a benzophenone compound, a tertiary amine compound, and a xanthone compound. Among these, a thioxanthone compound and an anthraquinone-based compound can be used preferably from the viewpoint of curability in deep portions.

Furthermore, among the sensitizers mentioned above, it is believed that a compound with functional groups such as an ester and amino group react with alkali-soluble resins mentioned above and photopolymerizable monomers mentioned below. The cured product of photosensitive resin composition has a partially cross-linked structure. As a result, the water absorption rate of the cured product can be further reduced. Examples of sensitizers with such functional groups include, for example, anthraquinone-based sensitizers represented by the following formula.

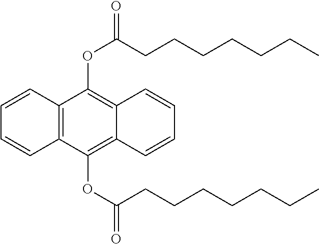 [SMILES: CCCCCCCC(=O)Oc1c2ccccc2c(OC(=O)CCCCCCC)c2ccccc12]

The anthraquinone-based sensitizer above described can be purchased commercially, for example, “ANTHRACURE UVS-581” (manufactured by Kawasaki Kasei Kogyo Co., Ltd.).

The amount of the sensitizer is preferably 0.01 to 10% by mass, and more preferably 0.01 to 3% by mass based on the entire photosensitive resin composition. As a result, the water absorption rate of the cured product can be reduced while the excellent resolution is maintained.

### <Inorganic Filler>

The photosensitive resin composition according to the present invention includes an inorganic filler. By adding inorganic fillers, the water absorption rate of the cured product can be reduced, as well as the cured product can acquire the required strength, and the coefficient of thermal expansion can be reduced. The conventionally known inorganic filler can be used. Examples of inorganic fillers include, in particular, silica, talc, mica, aluminum oxide, calcium oxide, magnesium oxide, zinc oxide, calcium carbonate, magnesium carbonate, fly ash, dehydrated sludge, kaolin, clay, calcium hydroxide, aluminum hydroxide, magnesium hydroxide, hydrotalcite, aluminum silicate, magnesium silicate, calcium silicate, wollastonite, potassium titanate, magnesium sulfate, calcium sulfate, magnesium phosphate, sepiolite, zonolite, boron nitride, aluminum borate, silica balloon, glass flake, glass balloon, magnetic powders such as iron-making slag, copper, iron, iron oxide, Sendust, alnico magnets, and a variety of ferrites, cement, glass powder, Neuburg siliceous earth, diatomaceous earth, antimony trioxide, magnesium oxysulfate, hydrated aluminum, hydrated gypsum, alum, and barium sulfate and the like. One kind of inorganic filler may be used solely; or two or more kinds may be used in combination. Of the above, silica is preferable.

The average particle diameter (D50) of the inorganic filler is preferably 0.1 to 100 μm, and more preferably 0.1 to 50 μm It is to be noted that the average particle diameter refers to the particle diameter at 50% cumulative volume, as obtained by using the laser diffraction scattering type particle size distribution measurement method. The average particle size of the filler refers to the value measured as described above for the filler before the photosensitive resin composition is prepared (pre-stirred and kneaded).

It is required that the amount of the inorganic filler in the photosensitive resin composition is 85% or less based on the total amount of the photosensitive resin composition, in order to achieve both elastic modulus and water absorption of the cured product and the resolution. When the amount of the inorganic filler exceeds 85% by mass, the water absorption rate and warpage in the cured product is reduced while the resolution is insufficient. The amount of the inorganic filler is preferably 45 to 85% by mass, and more preferably 45 to 65% by mass.

The above filler may be surface-treated in order to enhance the dispersibility in the photosensitive resin composition. The water absorption rate of the cured product can be further reduced by using surface-treated filler. As a result, the warpage of the printed wiring board can be reduced. The surface treatment method is not particularly limited, and a commonly used known method may be used. However, it is preferable to treat the surface of inorganic filler with a surface treatment agent having a curable reactive group, for example, a coupling agent having a curable reactive group as an organic group.

Examples of curable reactive groups include photocurable reactive groups and thermosetting reactive groups. Examples of photocurable reactive groups include ethylenically unsaturated groups such as vinyl, styryl, methacryl, and acrylic groups. Among these, at least one of the vinyl groups and (meth)acrylic groups is preferable. Examples of thermosetting reactive groups include hydroxyl, carboxyl, isocyanate, amino, imino, epoxy, oxetanyl, mercapto, methoxymethyl, methoxyethyl, ethoxymethyl, ethoxyethyl, oxazoline groups and the like. Among these, at least one of the amino groups and epoxy groups is preferable. It is to be noted that the surface-treated inorganic filler may have a photopolymerizable reaction group in addition to a thermosetting reactive group.

As the coupling agent, coupling agents such as silane-based, titanate-based, aluminate-based, and zircoaluminate-based coupling agents can be used. Of these, a silane-based coupling agent is preferable. Examples of such silane-based coupling agents can include vinyl trimethoxysilane, vinyl triethoxysilane, N-(2-aminomethyl)-3-aminopropylmethyl dimethoxysilane, N-(2-aminoethyl)-3-aminopropyl trimethoxysilane, 3-aminopropyl triethoxysilane, 3-anilinopropyl trimethoxysilane, 3-glycydoxypropyl trimethoxysilane, 3-glycydoxypropylmethyl dimethoxysilane, 2-(3,4-epoxycyclohexyl)ethyl trimethoxysilane, 3-methacryloxypropyl trimethoxysilane, and 3-mercaptopropyl trimethoxysilane. These can be used solely or in combination. It is preferable that these silane-based coupling agents are previously immobilized on the surface of filler by adsorption or reaction. Here, the amount treated by the coupling agent with respect to 100 parts by mass of the spherical silica is preferably 0.5 to 10 parts by mass.

The surface-treated inorganic filler is only required to be contained in the resin layer in the state of surface-treated. Although the inorganic filler and the silane coupling agent may be separately added into the photosensitive resin composition and the inorganic filler may be surface-treated in the composition, it is preferable to add the inorganic filler with surface treatment beforehand. By adding the inorganic filler with surface treatment to the photosensitive resin composition, it is possible to prevent cracks caused by silane coupling agents which may remain when the inorganic filler and the silane coupling agent are separately added. When surface treatment is carried out in advance, it is preferable to combine a pre-dispersing liquid in which inorganic fillers are pre-dispersed into an alkali-soluble resin or solvent etc. It is more preferable to pre-disperse the surface-treated inorganic filler in the solvent and add this pre-dispersing liquid to the composition, or to add the pre-dispersing liquid to the composition after sufficient surface-treating of a surface-untreated inorganic filler when pre-dispersing it into the solvent.

### <Photopolymerizable Monomer>

The photosensitive resin composition according to the present invention may contain the photopolymerizable monomer. The photosensitive monomer is a monomer having ethylenically unsaturated double bond. Examples of such photopolymerizable monomers include commonly used known polyester (meth)acrylate, polyether (meth)acrylate, urethane (meth)acrylate, carbonate (meth)acrylate, and epoxy (meth)acrylate. To be specific, at least one selected as appropriate from the following can be used: alkyl acrylates such as 2-etylhexylacrylate or cyclohexylacrylate; hydroxyalkyl acrylates such as 2-hydroxyethyl acrylate or 2-hydroxy propyl acrylate; mono- or diacrylates of alkylene oxide derivatives such as ethylene glycol, propylene glycol, diethylene glycol, or dipropylene glycol; acrylamides such as N,N-dimethyl acrylamide, N-methylolacrylamide, or N,N-dimethylamino propyl acrylamide; amino alkyl acrylates such as N,N-dimethylamino ethyl acrylate or N,N-dimethylamino propyl acrylate; polyalcohols such as hexanediol, trimethylolpropane, pentaerythritol, ditrimethylolpropane, dipentaerythritol, or trishydroxyethyl isocyanurate or alkylene oxide adduct thereof, or polyacrylates such as ε-caprolactone adduct thereof; phenols such as phenoxy acrylate or bisphenol A diacrylate, or polyacrylates such as alkylene oxide adduct thereof; acrylates of glycidyl ether such as glycerin diglycidyl ether, trimethylolpropane triglycidyl ether, or triglycidyl isocyanurate; and, besides the above, acrylates obtained by subjecting polyols such as polyether polyol, polycarbonate diol, hydroxyl-terminated polybutadiene, or polyester polyol to direct acrylation or urethane acrylation via diisocyanate, and melamine acrylates; and each of methacrylates corresponding to the above-mentioned acrylates. Such photopolymerizable monomer can also be used as a reactive diluent.

One kind of photopolymerizable monomer can be used solely; or two or more kinds can be used in combination. The amount of the photopolymerizable monomer is preferably 0.5 to 30 parts by mass based on 100 parts by mass of the carboxyl group-containing resin in terms of solid content. When the amount of the photopolymerizable monomer is 0.5 parts by mass or more, the photocurable properties are good, and pattern formation is easy in alkaline development after active energy ray irradiation. In addition, when the amount of the photopolymerizable monomer is 30 parts by mass or less, halation is less likely to occur, and good resolution can be provided.

### <Thermosetting Component>

The photosensitive resin composition according to the present invention may contain the thermosetting component. Examples of thermosetting components include, a commonly-used known thermosetting component such as an isocyanate compound, a blocked isocyanate compound, an amino resin, a maleimide compound, a benzoxazine resin, a carbodiimide resin, a cyclocarbonate compound, an epoxy compound, an oxetane compound, or an episulfide resin. Of these, the preferred thermosetting component is an epoxy resin.

Examples of epoxy resins include bisphenol A type epoxy resin, bisphenol F type epoxy resin, hydrogenated bisphenol A type epoxy resin, brominated bisphenol A type epoxy resin, bisphenol S type epoxy resin, phenol novolac type epoxy resin, cresol novolac type epoxy resin, novolac type epoxy resin of bisphenol A, biphenyl type epoxy resin, naphthalene type epoxy resin, dicyclopentadiene type epoxy resin, and triphenylmethane type epoxy resin. One kind of these epoxy resins may be used solely; or two or more kinds may be used in combination.

Examples of commercially available epoxy resins include: jER 828, 806, 807, YX8000, YX8034, and 834 manufactured by Mitsubishi Chemical Corporation; YD-128, YDF-170, ZX-1059, and ST-3000 manufactured by NIPPON STEEL Chemical & Material CO., LTD.; EPICLON 830, 835, 840, and 850, N-730A, and N-695 manufactured by DIC Corporation; and RE-306 manufactured by Nippon Kayaku Co., Ltd.

The equivalent of the epoxy group of epoxy resin in the photosensitive resin composition is preferably 0.5 to 2.5 equivalent based on 1 equivalent of the carboxyl group of carboxyl group-containing photosensitive resin in terms of solid content. By making the equivalent of the epoxy group of epoxy resin 0.5 equivalent or more, remaining carboxyl groups in the cured product can be prevented, and good thermal resistance, alkaline resistance, electrical insulation, and the like can be achieved. In addition, by making the above-mentioned amount to 2.5 equivalents or less, remaining of low molecular weight cyclic (thio) ether group on the dried coating film can be prevented to ensure good strength of the cured product.

### <Heat-Curing Catalyst>

The photosensitive resin composition according to the present invention may contain a heat-curing catalyst to promote curing of the above-described thermosetting component. Examples of heat-curing catalysts include imidazole, imidazole derivatives such as 2-methylimidazole, 2-ethylimidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole; dicyandiamide, amine compounds such as benzyldimethylamine, 4-(dimethylamino)-N,N-dimethylbenzylamine, 4-methoxy-N,N-dimethylbenzylamine, and 4-methyl-N,N-dimethylbenzylamine; hydrazine compounds such as adipic dihydrazide and sebacic dihydrazide; and phosphorus compounds such as triphenylphosphine. In addition, examples of one that is commercially available include 2MZ-A, 2MZ-OK, 2PHZ, 2P4BHZ, 2P4 MHZ (all are trade names of imidazole-based compounds), which are manufactured by Shikoku Chemicals Corporation; and U-CAT, 3513N (trade names of dimethyl amine compounds), DBU, DBN, U-CAT SA 102 (all are bicyclic amidine compounds and salts thereof) which are manufactured by San-Apro Ltd.

The catalyst is not limited to the above compounds; and may be a heat-curing catalyst for an epoxy resin or an oxetane compound one that promotes a reaction of at least one kind of an epoxy group and an oxetanyl group with a carboxyl group. The catalyst may be used solely; or two or more kinds thereof may be mixed to be used. In addition, guanamine, acetoguanamine, benzoguanamine, melamine, and S-triazine derivatives such as 2,4-diamino-6-methacryloyloxyethyl-S-triazine, 2-vinyl-2,4-diamino-S-triazine, a 2-vinyl-4,6-diamino-S-triazine·isocyanuric acid adduct, and a 2,4-diamino-6-methacryloyloxyethyl-S-triazine·isocyanuric acid adduct can be used. Preferably, these compounds which function also as adhesion imparting agents are used in conjunction with the heat curing catalyst.

One kind of heat-curing catalyst can be used solely; or two or more kinds can be used in combination. The amount of the heat-curing catalyst is preferably 0.01 to 30 parts by mass, and more preferably 0.1 to 20 parts by mass based on 100 parts by mass of the carboxyl group-containing resin in terms of solid content, from the viewpoint of the storage stability of the resin composition and the heat resistance of the cured coating film.

### <Other Components>

The photosensitive resin composition according to the present invention may further be combined, besides the above components as necessary, with a colorant, an elastomer, a mercapto compound, an urethanation catalyst, a thixotropic agent, an adhesion promoter, a block copolymer, a chain transfer agent, a polymerization inhibitor, a copper damage inhibitor, an antioxidant, an anti-rust agent, a thickener such as organic bentonite or montmorillonite, at least one kind of antifoaming agents and leveling agents based on silicone, fluorine, polymer, and the like, and a flame retardant of a phosphorus compound such as hypophosphorous acid, a phosphate ester derivative, or a phosphazene compound. As for these, products known in the field of electronic materials can be used.

The photosensitive resin composition of the present invention may be combined with organic solvents from the viewpoint of ease of preparation and coating property. As the organic solvents, a commonly-used known organic solvent such as, ketones such as methyl ethyl ketone and cyclohexanone; aromatic hydrocarbons such as toluene, xylene, and tetramethylbenzene; glycol ethers such as cellosolve, methyl cellosolve, butyl cellosolve, carbitol, methyl carbitol, butyl carbitol, propylene glycol monomethyl ether, dipropylene glycol monomethyl ether, dipropylene glycol diethyl ether, diethylen glycol monomethyl ether acetate, and tripropylene glycol monomethyl ether; esters such as ethyl acetate, butyl acetate, butyl lactate, cellosolve acetate, butyl cellosolve acetate, carbitol acetate, butyl carbitol acetate, propylen glycol monomethyl ether acetate, dipropylen glycol monomethyl ether acetate, and propylene carbonate; aliphatic hydrocarbons such as octane and decane; petroleum solvents such as petroleum ether, petroleum naphtha, and solvent naphtha can be use. These organic solvents can be used solely; or two or more kinds can be used in combination.

The amount of organic solvent combined in the photosensitive resin composition can be changed as appropriate depending on the materials constituting the photosensitive resin composition, for example, it can be set to 30 to 300 parts by mass based on 100 parts by mass of the carboxyl group-containing resin (A) in terms of solid content.

The photosensitive resin composition according to the present invention may be formed into a dry film to use or used in liquid form. When photosensitive resin composition is used in liquid form, it can be used as either a one-pack type, a two-pack type, or multi-pack type.

### <Dry Film>

The photosensitive resin composition described above can also be in the form of a dry film, comprising a first film and a resin layer formed on the first film composed of the photosensitive resin composition, The cured product of the present invention is provided by curing the photosensitive resin composition described above or the resin layer of dry film described above.

The first film in the dry film according to the present invention refers to a film which is at least adhered to the resin layer when carrying out laminating by heating and the like such that the resin layer composed of a photosensitive resin composition formed on the dry film is in contact with the substrate such as a board and molding. The first film may be detached from the resin layer in the step after laminating. In particular, in the present invention, it is preferable to detach the resin layer in the step after exposure.

To prepare a dry film, the photosensitive resin composition according to the present invention can be diluted with an organic solvent to adjust to an appropriate viscosity; applied on the surface opposed to the first film by using a comma coater, a blade coater, an LIP coater, a rod coater, a squeeze coater, a reverse coater, a transfer roll coater, a gravure coater, a spray coater, or the like such that a uniform thickness is attained; and dried usually at a temperature of 50 to 130° C. for 1 to 30 minutes, thereby obtaining a coating film. The thickness of the coating film is not in particular restricted; and is in general selected as appropriate in a range of 1 to 150 μm and preferably 10 to 60 μm in the thickness after the drying.

As the supporting film, any commonly known film can be used without limitation. For example, films composed of thermoplastic resins such as polyester films such as polyethylene terephthalate or polyethylene naphthalate, polyimide films, polyamide-imide films, polypropylene films, or polystyrene films can be suitably used. Of these, polyester films are preferable from the viewpoint of thermal resistance, mechanical strength, ease of handling and the like. The laminate of these films can also be used as the first film.

In addition, from the viewpoint of improving the mechanical strength, films stretched in a uniaxial direction or a biaxial direction are preferable as the thermoplastic resin film described above.

The thickness of the first film can be, not in particular restricted, for example 10 μm to 150 μm.

After forming the resin layer of the present photosensitive resin composition on the first film, it is further preferable to laminate a detachable second film on the surface of resin layer, for the purpose of preventing dust from adhering to the surface of resin layer. The second film in the dry film according to the present invention refers to a film that is detached from the resin layer before laminating by heating and the like such that the resin layer side of dry film is in contact with the substrate such as a board and molding.

For the second film that can be detached from the resin layer, for example, polyethylene film, polytetrafluoroethylene film, polypropylene film, surface-treated paper and the like can be used. The adhesion between the resin layer and the second film only needs to be smaller than the adhesion between the resin layer and the first film when detaching the second film.

The thickness of the second film can be, not in particular limited, for example 10 μm to 150 μm.

### [Printed Wiring Board]

The printed wiring board of the present invention comprises a board and a cured coating film composed of the cured product provided on the board. The cured product of the present invention can be, as described above, provided from a photosensitive resin composition or a resin layer of dry film. The method for manufacturing the printed wiring board of the present invention is, for example, adjusting the viscosity of the present photosensitive resin composition suitably for coating methods by using the above organic solvents, then applying it onto the substrate with methods such as a dip coating method, a flow coating method, a roll coating method, a bar coating method, a screen printing method, a curtain coating method and the like, subsequently volatilizing and drying (transiently drying) the organic solvent contained in the composition at a temperature of 60 to 100° C. to form a tack-free resin layer. In a case of dry film, the resin layer is formed on the substrate by laminating it onto the substrate so that the resin layer contacts with the substrate by using a laminator or the like, then detaching the first film.

Examples of substrates described above can include, in addition to printed wiring boards on which a circuit is in advance formed with copper or the like and flexible printed wiring boards, all grades (FR-4 and the like) of copper clad laminates that use materials of copper clad laminates for high frequency circuit using paper phenol, paper epoxy, glass cloth epoxy, glass polyimide, glass cloth/non-woven fabric epoxy, glass cloth/paper epoxy, synthetic fiber epoxy, fluorine resin·polyethylene polyphenylene ether, polyphenylene oxide·cyanate, or the like, other metal boards, polyimide films, polyethylene terephthalate films, polyethylene naphthalate (PEN) films, glass boards, ceramic boards, and wafer substrates.

When in the form of the dry film, lamination onto the substrate is preferably carried out by using a vacuum laminator or the like under applied pressure and heating, By using such a vacuum laminator, when using the board on which the circuit is formed, even if the surface of circuit board has roughness, no air bubbles are mixed and improved filling up dents of the board surface is seen because the dry film is closely attached to the circuit board. The applied pressure condition is preferably about 0.1 to 2.0 MPa; and the heating condition is preferably 40 to 120° C.

If the photosensitive resin composition of the present invention contains an organic solvent, it is preferable to perform volatilization and drying after applying the photosensitive resin composition onto the surface of substrate. The volatilization and drying can be performed by using a hot air circulation drying furnace, an IR furnace, a hot plate, a convection oven, or the like (a method comprising countercurrent-contacting of a heated air in a dryer using one that includes a heat source in the mode of heating air by steam, and a method comprising spraying a substrate from a nozzle).

After forming a resin layer on the substrate, the substrate is selectively exposed to active energy rays through a photomask with a predetermined pattern, and an unexposed portion is developed by using a rare alkaline aqueous solution (e.g., 0.3 to 3 mass % sodium carbonate aqueous solution) to form a pattern of cured product. In the case of the dry film, after the exposure, the first film is detached from the dry film and development is carried out, thereby forming a cured product which is patterned on the substrate. If the film is in the form of a dry film form, the first film may be detached from the dry film before exposure, and then the exposed resin layer may be subjected to exposure and development, as long as the characteristics are not impaired. Furthermore, by thermal curing (for example, 100 to 220° C.) after irradiating the cured product with an active energy ray or by irradiating an active energy ray after thermal curing, or by final finishing curing (final curing) with thermal curing alone, a cured coating film with excellent properties such as adhesion and hardness can be formed.

When a cured product is made as described above, the elastic modulus of the cured product can also be adjusted according to the curing conditions. The elastic modulus is a physical property which indicates the degree of resistance to deformation of a cured product. For example, the degree of progress of the cross-linking reaction of reactive groups changes depending on the conditions of photocuring and thermosetting, and it also affects the elastic modulus of a cured product. In other words, if the degree of progress of the cross-linking reaction is varied, the strain amount in the cured product when stress has been applied is also changed, resulting different value of the elastic modulus.

An exposure apparatus used for the above described active energy ray irradiation only need to be an apparatus that includes a high pressure mercury vapor lamp, an ultrahigh pressure mercury vapor lamp, a metal halide lamp, a mercury short arc lamp, or the like, and radiates an ultraviolet ray of 350 to 450 nm, Further, a direct patterning apparatus (for example, a laser direct imaging apparatus that directly draws picture images by using a laser based on CAD data from a computer) can also be used. A source of lamp light or laser light of the direct patterning equipment may be a light with a maximum wavelength in a range of 350 to 450 nm. The exposure amount for the picture image formation varies in film thickness and the like, and can in general be set within a range of 10 to 1000 mJ/cm² and preferably 20 to 800 mJ/cm².

As the development method above, a dipping method, a shower method, a spray method, a brush method, or the like can be used. Further, as a development liquid, an aqueous solution of alkali such as potassium hydroxide, sodium hydroxide, sodium carbonate, potassium carbonate, sodium phosphate, sodium silicate, ammonia, or amines can be used.

After the cured coating film is formed on the substrate as described above, components such as electronic devices are mounted on the substrate by using solder reflow processing. Solder reflow processing can be carried out by using conventionally known methods. In addition, solder reflow is in general carried out under processing conditions of 245 to 260° C. for 5 to 10 seconds.

The photosensitive resin composition or dry film of the present invention is suitably used for manufacturing electronic components such as printed wiring board, and is more suitably used for forming a permanent coating film. At that time, a cured product is formed by using the photosensitive resin composition or dry film of the present invention according to the above-mentioned method or the like. When the photosensitive resin composition or dry film resin layer of the present invention is insulating, it is suitably used to form a solder resist, a coverlay, or an interlayer insulation layer. It is to be noted that the photosensitive resin composition according to the present invention may also be used to form a solder dam.

### Examples

By way of example, the present invention will be described in detail below. It is to be noted that the following terms “part” and “%” are all on mass basis unless otherwise specified.

### Synthesis Example 1 (Synthesis of Carboxyl Group-Containing Resin A)

To an autoclave that included a thermometer, a nitrogen introduction apparatus, alkylene oxide introduction apparatus, and a stirring apparatus, 119.4 parts by mass of novolak-type cresol resin (trade name “Shonol CRG951, manufactured by Aica Kogyo Company, Ltd., OH equivalent: 119.4), 1.19 parts by mass of potassium hydroxide, and 119.4 parts by mass of toluene were introduced. The system was subjected, while stirring, to internal nitrogen replacement and raised the temperature. Subsequently, 63.8 parts by mass of propylene oxide was gradually added dropwise; and the resulting mixture was allowed to proceed a reaction at 125 to 132° C. and 0 to 4.8 kg/cm² for 16 hours. Thereafter, the resultant was cooled to room temperature; and this reaction solution was added and mixed with 1.56 parts by mass of 89% phosphoric acid while neutralizing potassium hydroxide, thereby obtaining a propylene oxide reaction solution of novolak-type cresol resin [solid content: 62.1%; hydroxyl value of 182.2 mg KOH/g (307.9 g/eq.)]. In the propylene oxide reaction solution, an average of 1.08 mol of propylene oxide was added per equivalent of phenolic hydroxyl group.

To a reactor having a stirring apparatus, a thermometer, and an air blowing tube, 293.0 parts by mass of the obtained propylene oxide reaction solution of novolak-type cresol resin, 43.2 parts by mass of acrylic acid, 11.53 parts by mass of methanesulfonic acid, 0.18 parts by mass of methylhydroquinone, and 252.9 g parts by mass of toluene were introduced. Air was blown therein at a rate of 10 ml/min. The resultant was allowed to proceed a reaction at 110° C. for 12 hours while stirred. 12.6 parts by mass of generated by the reaction was allowed to distill as an azeotropic mixture with toluene. Thereafter, the resultant was cooled to room temperature; and the obtained reaction solution was neutralized with 35.35 parts by mass of a 15% aqueous sodium hydroxide solution and then washed with water. Thereafter, toluene was replaced with 118.1 parts by mass of diethylene glycol monoethyl ether acetate and distilled away in an evaporator, thereby obtaining a novolak-type acrylate resin solution.

Subsequently, to a reactor that includes a stirring apparatus, a thermometer, and an air blowing tube, 332.5 parts by mass of the obtained novolak-type acrylate resin solution and 1.22 parts by mass of triphenylphosphine was introduced. Air was blown therein at a rate of 10 ml/min; and 60.8 parts by mass of tetrahydrophthalic anhydride was, while stirred, gradually added thereto. The resultant was allowed to proceed with a reaction at 95 to 101° C. for six hours. After cooling, the resultant was collected.

In this manner, a solution of carboxyl group-containing resin A (solid content: 65%; solid acid value: 87.7 mg KOH/g) was obtained.

### <Preparation of Inorganic Filler>

The following two types of inorganic filler were prepared. 70 g of spherical silica (SFP-30M manufactured by Denka Company Ltd., average particle diameter: 600 nm), 28 g of PMA (propylene glycol monomethyl ether acetate) as a solvent, and 2 g of silane coupling agent with methacrylate group (KBM-503 manufactured by Shin-Etsu Chemical Co., Ltd.) were uniformly dispersed to provide a surface-treated inorganic filler (70% solid content),

70 g of spherical silica (SFP-30M manufactured by Denka Company Ltd., average particle diameter: 600 nm) and 28 g of PMA (propylene glycol monomethyl ether acetate) as a solvent were uniformly dispersed to provide a surface-untreated inorganic filler (70% solid content).

### <Preparation of Photosensitive Resin Compositions>

By combining each component listed in Table 1 below and mixing with a triple roll mill at room temperature, each photosensitive resin composition listed in the table (Examples 1 to 6 and Comparative Examples 1 to 2) were obtained. It is to be noted that each numerical value in the table indicates the parts by mass.

Yet, each component *1 to *7 in the table below is as follows:
*1: acylphosphine oxide-based photoinitiator (Omnirad 819 manufactured by IGM Resins B.V.)
*2: ANTHRACURE UVS-581 (manufactured by Kawasaki Kasei Kogyo Co., Ltd.)
*3: KAYACURE DETX-S (manufactured by Nippon Kayaku Co., Ltd.)
*4: dipentaerythritol hexaacrylate (manufactured by Sanyo Chemical Industries, Ltd.)
*5: phenol novolac type epoxy resin (manufactured by DIC Corporation)
*6: melamine (manufactured by Nissan Chemical Corporation, D5=0.5 μm, 55% solid content)
*7: dicyandiamide (manufactured by Mitsubishi Chemical Corporation, 73% solid content)
*8: a mixture of phthalocyanine blue and PIGMENT Yellow 147 (containing ratio 57:43, 10% solid content) It is to be noted that the numerical values in the table indicate the amount in a solution containing solid contents and solvents.

### <Measurement of Water Absorption Rate of Cured Product>

For a photosensitive resin composition obtained as described above (Example 1 to 6 and Comparative Example 1 to 2), a photosensitive resin composition was applied over the entire surface of copper clad laminate board (MCL-E-770G manufactured by Showa Denko K.K., copper thickness 18 μm) with a thickness of 200 μm and size of 100×100 mm as a support so that the cured film thickness is 20 μm. Then, the resultant was dried in a hot air circulation drying furnace (DF610 manufactured by Yamato Scientific Co., Ltd.) at 80° C. for 30 minutes to form a dried coating film. Subsequently, the dried coating film was exposed by using a UV conveyor furnace (KUV-28351-XK-DM manufactured by Toshiba Corporation) equipped with a metal halide lamp as a light source under conditions as follows: an integrated exposure amount of 1000 mJ/cm² (38 mW/cm²×26s) at a wavelength of 365 nm. Thereafter, the resultant was heated at 150° C. for 60 minutes to cure the coating film. The cured coating film was then detached from the support to obtain a cured product.

In addition, in the photosensitive resin composition of Example 1, a cured coating film was formed in the same manner as in Example 1 to obtain a cured product (Example 7), except that the integrated exposure amount was changed to 500 mJ/cm² (38 mW/cm²×13 s), and the heating conditions were changed to 120° C. for 60 minutes.

The 30 mg of cured product obtained was placed on a weighing dish, and the mass of each cured product was measured after leaving it for 1 hour in an environment at 100° C. (absolute dry condition) (the resulting mass at this time is set as W₀).

Then, the mass of the cured product after leaving it for 60 minutes in an environment with a temperature of 25° C. and a relative humidity of 10% was measured (the resulting mass at this time is set as W₁₀).

In addition, the mass of the cured product after leaving it for 60 minutes in an environment with a temperature of 25° C. and a relative humidity of 60% was also measured (the resulting mass at this time is set as W₆₀).

The water absorption rates A and B were calculated from the following formula based on the resulting mass.

$$the water absorption rate A ( \% ) = ( {W}_{10} - {W}_{0} ) / {W}_{0} \times 100$$

$$the water absorption rate B ( \% ) = ( {W}_{60} - {W}_{0} ) / {W}_{0} \times 100$$

The difference between water absorption rates A and B (B−A) was as shown in Table 1 below.

### <Measurement of Elastic Modulus of Cured Product>

For each cured product obtained as described above, the cured product was cut to prepare a test piece in a size of 10 mm×80 mm. The stress-strain curve was obtained by using a tensile testing machine in accordance with JIS K 7127 under conditions as follows: distance between fixtures 40 mm, tensile speed 1 mm/min, and temperature 25° C. The elastic modulus of the cured product was determined as the slope of line calculated for the stress between 2N and 7N for the resulted curve. The elastic modulus of each cured product was as shown in Table 1 below.

### <Evaluation of Cured Product>

### (1) Warpage of Board

In the same manner as described above, a board composed of a cured coating film (a cured product) having a thickness of 20 μm formed on a copper clad laminate board was left for one hour in an environment with a temperature of 25° C. and a relative humidity of 60%. The amount of warping in four corners of the board was measured by using a caliper, and evaluated with the following criteria.
∘: The average amount of warping in the 4 corners is less than 5.5 mm.
Δ: The average amount of warping in the 4 corners is 5.5 mm or more and less than 7.5 mm,
x: The average amount of warping in the 4 corners is 7.5 mm or more.

The evaluation results are shown in Table 1 below.

### (2) Resolution (Undercut)

As above, each photosensitive resin composition was applied over the entire surface of copper clad laminate board so that the cured film thickness is 20 μm. Then, the resultant was dried in a hot air circulation drying furnace (DF610 manufactured by Yamato Scientific Co., Ltd.) at 80° C. for 30 minutes to form a dried coating film. Thereafter, the first film (Lumirror T60 manufactured by Toray Industries, Inc., thickness of 125 μm) was laminated onto the resulting dried coating film.

The dried coating film was pattern exposed at the optimum exposure amount through a negative mask with SRO of 80 μm by using an exposure device (Oak Manufacturing Co., Ltd. HMW-680-GW 20) equipped with a metal halide lamp as a light source. Here, the optimal exposure amount was set as an amount of 6 steps in a 21-step sensitivity step tablet, which remains when the dried coating film obtained above was exposed by an exposure device equipped with a metal halide lamp via the step tablet, and developed for 60 seconds under the conditions of a spray pressure of 0.2 MPa with Na₂C O₃ aqueous solution in 0.2% by mass at a liquid temperature of 3 0° C.

The first film was then detached, and development was carried out by using a concentration of 0.2% by mass of Na₂CO₃ aqueous solution at a temperature of 30° C., followed by washing with water. Finally, a test piece for the resolution evaluation was made by cu ring the resultant at 150° C. for 60 minutes.

For the resulting test piece, the resolution was evaluated by using the following criteria.
∘: The ratio of a diameter of the upper part of opening to an opening of the bottom part is 0.85 or more.
Δ: The ratio of a diameter of the upper part of opening to an opening of the bottom part is less than 0.85 and 0.85 or more.
x: The ratio of a diameter of the upper part of opening to an opening of the bottom part is less than 0.70.

The evaluation results are shown in Table 1 below.

TABLE 1

| | | | | | | | | | Comparative | |
|---|---|---|---|---|---|---|---|---|---|---|
| | | Example | | | | | | | Example | |
| Composition of photosensitive resin composition | | 1 | 2 | 3 | 4 | 5 | 6 | 7 | 1 | 2 |
| Alkali-soluble resin | varnish A | 154 | 154 | 154 | 154 | 154 | 154 | 154 | 154 | 154 |
| Photoinitiator | Omnirad 819 *¹ | 10 | 10 | 10 | 10 | 10 | 10 | 10 | 10 | 10 |
| Sensitizer | UVS-581 *² | 1 | — | 1 | — | — | — | 1 | — | 1 |
| | DETX-S *³ | — | — | — | — | — | 1 | — | — | — |
| Inorganic filler | surface-treated inorganic | 475 | 475 | — | 1160 | 240 | 475 | 475 | 2600 | — |
| | filler | | | | | | | | | |
| | surface-untreated | — | — | 475 | — | — | — | — | — | 111 |
| | inorganic filler | | | | | | | | | |
| Photopolymerizable | DA-600 *⁴ | 15 | 15 | 15 | 15 | 15 | 15 | 15 | 15 | 15 |
| monomer | | | | | | | | | | |
| Thermosetting | N-730-A *⁵ | 57 | 57 | 57 | 57 | 57 | 57 | 57 | 57 | 57 |
| component | | | | | | | | | | |
| Thermosetting | melamine *⁶ | 25 | 25 | 25 | 25 | 25 | 25 | 25 | 25 | 25 |
| catalyst | DICY *⁷ | 1 | 1 | 1 | 1 | 1 | 1 | 1 | 1 | 1 |
| Colorant | blue pigment and yellow | 10 | 10 | 10 | 10 | 10 | 10 | 10 | 10 | 10 |
| | pigment *⁸ | | | | | | | | | |
| Water absorption rate A of cured product (%) | | 0.08 | 0.08 | 0.1 | 0.05 | 0.1 | 0.1 | 0.1 | 0.05 | 0.2 |
| Water absorption rate difference | | 0.25 | 0.25 | 0.3 | 0.2 | 0.3 | 0.3 | 0.3 | 0.2 | 0.5 |
| between cured products (B-A) (%) | | | | | | | | | | |
| Inorganic filler amount (mass %) | | 64 | 64 | 64 | 81 | 47 | 64 | 64 | 91 | 29 |
| Elastic modulus (GPa) | | 8 | 8 | 7 | 11 | 5 | 8 | 6 | 13 | 3 |
| Evaluation | Warpage of board | ◯ | ◯ | Δ | ◯ | Δ | ◯ | Δ | ◯ | X |
| | Resolution (undercut) | ◯ | Δ | ◯ | Δ | ◯ | Δ | ◯ | X | ◯ |

As is apparent from Table 1, the photosensitive resin compositions (Examples 1 to 7) have a high resolution and can reduce the warpage of printed wiring board. In these photosensitive resin compositions, the inorganic filler content is 85% or less by mass, the elastic modulus of the cured product is in the range of 4 to 12 GPa, the water absorption rate A is 0.3% or less by mass, and the difference in water absorption (B−A) is 0.3% or less.

On the other hand, the cured product (Comparison Example 1) comprising a photosensitive resin composition with an excessive amount of inorganic filler has a water absorption rate A of 0.3% or less and a water absorption rate difference (B−A) of 0.3% or less. However, although the elastic modulus of the cured product is outside the range of 4 to 12 GPa, and it can reduce the warpage of printed wiring board, the resolution is insufficient. In addition, it is found that although the cured product (Comparison example 2) comprising a photosensitive resin composition with a reduced amount of inorganic filler to maintain resolution improves its resolution, the elastic modulus exceeds 12 GPa, and the water absorption rate difference (B−A) also exceeds 0.3% by mass, thereby it is not possible to reduce the warpage of the board.

1. A cured product of a photosensitive resin composition comprising at least an alkali-soluble resin, a photoinitiator, and an inorganic filler, wherein
the inorganic filler is contained in an amount of 85% or less by mass based on a total amount of the photosensitive resin composition,
an elastic modulus of the cured product is 4 to 12 GPa, and
the cured product satisfies the following conditions:
$$A \leq 0.3 \%$$
$$and$$
$$B - A \leq 0.3$$
where A (%) is a water absorption rate of the cured product after leaving it for 60 minutes in an environment with a temperature of 25° C. and a relative humidity of 10%, and
where B (%) is a water absorption rate of the cured product after leaving it for 60 minutes in an environment with a temperature of 25° C. and a relative humidity of 60%.

2. The cured product according to claim 1, wherein the inorganic filler is contained in an amount of 45 to 65% by mass based on the total amount of the photosensitive resin composition.

3. The cured product according to claim 1, wherein the inorganic filler is surface-treated with a silane coupling agent.

4. The cured product according to claim 1, wherein the photosensitive resin composition further comprises a sensitizer in an amount of 0.01 to 10% by mass based on the total amount of the photosensitive resin composition.

5. The cured product according to claim 4, wherein the sensitizer is an anthraquinone-based sensitizer having an ester bond.

6. A printed wiring board having a board and a coating film composed of the cured product according to claim 1 provided on the board.
